(19) United States
(12) Patent Application Publication
(10) Pub. No.: US 2021/0272039 A1
(43) Pub. Date: Sep. 2, 2021

(54) SYSTEMS AND METHODS FOR EVALUATING A MICROTRANSIT SERVICE

(71) Applicant: Ford Global Technologies, LLC, Dearborn, MI (US)

(72) Inventors: Richard Twumasi-Boakye, Taylor, MI (US); Yifan Chen, Ann Arbor, MI (US); James Fishelson, Ypsilanti, MI (US); Xiaolin Cai, Ann Arbor, MI (US); Archak Mittal, Dearborn, MI (US); Andrea Broaddus, Berkeley, CA (US); Seema Jain, Novi, MI (US); Eric H. Wingfield, Ann Arbor, MI (US)

(73) Assignee: Ford Global Technologies, LLC, Dearborn, MI (US)

(21) Appl. No.: 16/805,090

(22) Filed: Feb. 28, 2020

(51) Int. Cl. G06Q 10/06; G06Q 10/04; G06F 30/20

(52) U.S. Cl. CPC G06Q 10/06375; G06Q 10/06393; G06Q 50/30; G06F 30/20; G06Q 10/047

(57) ABSTRACT

The present disclosure relates to methods and systems for performing a cost-benefit analysis of a microtransit service, including a method utilizing both transportation simulation and experimental design in connection with the cost-benefit analysis.

### TECHNICAL FIELD

The present disclosure relates to a method and computer system for performing a cost-benefit analysis in evaluating a microtransit service that utilizes both transportation simulation and experimental design in connection with the analysis.

### BACKGROUND

The simulation of transportation systems involves planning, designing, and operating of transportation systems through mathematical modeling of the transportation systems in question (e.g., freeway junctions, arterial routes, roundabouts, downtown grid systems, etc.). Simulation of transportation systems is an ever-expanding discipline. Various national and local transportation agencies, academic institutions, and consulting firms use simulation to aid in their management of transportation networks.

Transportation simulation studies offer important benefits over conventional transportation planning studies for complicated scenarios. Transportation simulation can also produce attractive visual demonstrations of present and future transportation scenarios.

Microtransit is a fast-growing portion of the transportation system and represents a broad range of shared mobility services between private vehicles and public transit, with varying degrees/types of routing and sharing. One form of microtransit is Demand Responsive Transit (DRT), that offers flexible routing and/or flexible scheduling of, e.g., minibus vehicles. Typically, microtransit providers build routes to match demand (trips) and supply (driven vehicles) and extend the efficiency and accessibility of the transit service. This concept, known broadly as Mobility-as-a-Service (MaaS), is a highly dynamic and hyper-competitive expanding market. However, most transportation network companies currently run these services at a financial loss for reasons including unreasonable non-revenue movement of vehicles and unrealistic business models.

There is a current need for a method and system for evaluating the profitability of deploying microtransit and other shared mobility services for different areas of interest. In fact, there are no known methods for evaluating the economic viability of business-to-consumer (B2C) microtransit services by considering a holistic, comprehensive approach that entails transportation modeling concepts, microtransit service parameters, feasible service types, system level benefits, and financial profitability.

To the contrary, existing techniques for evaluating shared mobility services have been limited in scope. For example, CN108292473 A, assigned to Zoox, Inc., discloses a system for simulating the operation of an autonomous vehicle in a fleet, including the interaction between remote operator manager and autonomous vehicle.

US20160234648 A1 discloses a method for generating a personalized route for travel based on calculated and recorded route experience information. Similarly, U.S. Pat. No. 10,203,220 B2, assigned to Polaris Industries, Inc., discloses a mobile application that allows a user to “preview” a trip that is selected, for example, by providing a user-perspective “fly-through” view or simulation of a selected route, based on trail photos or videos collected in the database.

The above cited references however do not disclose a method for performing a cost-benefit analysis on a variety of microtransit systems, much less the ability to simulate and compare various alternative microtransit systems or modalities prior to implementing the system.

It is with respect to these and other considerations that the disclosure herein is presented.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 is a flow diagram illustrating an overall cost-benefit analysis method according to the disclosed method.

FIG. 2 is a second flow diagram illustrating simulation/experimental design analysis according to the disclosed method.

FIG. 3 is a third flow diagram illustrating another cost-benefit analysis method according to the disclosed method.

FIG. 4 is an example computing environment according to embodiments of the present disclosure.

### DETAILED DESCRIPTION

### Overview

The present disclosure relates to a method and system for evaluating the feasibility of integrating microtransit services into transportation systems in desired locations. This disclosure includes the ability to evaluate special use-cases, such as first/last mile services, and use microtransit to serve specific trip purposes (e.g. home-based-work trips), among others.

The present disclosure further relates to a method and system for providing transportation modeling evaluation/optimization of a microtransit service concept before any hardware assets are committed to operations (e.g., before establishing/purchasing a fleet of service vehicles and/or hiring a team of drivers for piloting the vehicles).

One example embodiment can include a method for microtransit system evaluation/optimization in a geographic area. The method may include running a series of full-factorial service experiments to identify the impact of certain selected independent variables on a proposed microtransit service from the different perspectives of the travelers, the system operators, and local governments. In this regard, the independent variables may include a number of service vehicles (i.e., fleet size), service areas, maximum waiting times, a maximum detour factor, one or more service rates, unserved demand, service hours, pick-up locations and drop-off locations.

The factors that may be determined and analyzed by the disclosed method include a maximum wait time, a maximum detour factor, i.e., reflecting how much extra time a passenger would be willing to spend on microtransit versus private transport, a demand for a particular transit service, pick-up and drop-off location density; and a number of available service vehicles, including fleet size and vehicle service hours.

These and other advantages of the present disclosure are provided in greater detail herein.

### Illustrative Embodiments

The disclosure will be described more fully hereinafter with reference to the accompanying drawings, in which exemplary embodiments of the disclosure are shown, are not intended to be limiting.

As employed in the present disclosure, a wide variety of services may be encompassed by the term “microtransit.” For example, “city-scale” deployment of microtransit services can include, but are not limited to (i) first-mile/last-mile shuttles, (ii) non-emergency medical transportation (NEMT), (iii) replacement for low-frequency/low utilization buses, (iv) park-and-ride, (v) event-transportation, (vi) service expansion for transit authorities, and (vii) alternative mobility services, e.g. e-scooters, among others.

Specific examples of microtransit modalities also include dynamic shuttles, shared taxis, fixed route services such as Via® and Chariot °, for example, and passenger drive sharing.

Embodiments of the present disclosure describe a method and system that utilize a transportation network simulation program configured to identify the best strategy to deploy and to develop a microtransit service customized for a selected geographical area. Embodiments describe creation of transportation network simulation models that may be used to evaluate microtransit systems using various predefined performance measures. Organizations, cities, and others may apply techniques and systems described herein to determine optimal transit solutions according to geographically defined areas (e.g., geo-bound areas). By way of an introduction to some concepts described in the present disclosure, several terms are discussed in the following paragraphs.

Transportation network simulation models simulate how demand and supply interact in transportation systems. These models allow the calculation of performance measures and user flows for each supply element (travel connection also known as a network link), resulting from origin-destination demand flows, user path choice behavior, and the reciprocal interactions between supply and demand.

Historically, transportation models were sometimes divided into three related categories: (microscopic, mesoscopic, and macroscopic). Microscopic models continuously or discretely predict the state of individual vehicles and primarily focus on individual vehicle speeds and locations. On the other end of the scale, macroscopic models may aggregate a description of traffic flow associated with a particular transportation modality, and measure effectiveness, of those factors, which may include, for example, transportation speed, flow, and use density, among other factors. Mesoscopic models can include aspects of both macro and microscopic models. The mesoscopic models may fill the gap between an aggregate level approach of macroscopic models and the individual interactions of the microscopic models by describing the traffic entities at a high level of detail, while their behavior and interactions are designed at a lower level of detail.

One example of a class of macroscopic models is called Macroscopic Transportation Simulation Tools (MTST). A macroscopic simulation model can be based on the deterministic relationships of the flow, speed, and density of the traffic streams associated with various modalities of transit services. The simulation in a macroscopic model can take place on a section-by-section basis (that is, by geo-fenced areas such as particular city blocks, for example) rather than by tracking individual vehicles.

As a simulation model, MTSTs can be a supply and demand-based tool. That is, an MTST links the current transport supply to transport demand in order to simulate the system allowing an infrastructure designer or manager to create a network assignment from supply and demand data. MTSTs may employ transportation data from a variety of sources. For example, they are capable of importing private transportation data and public transportation data from a variety of commercially available sources, such as Shape, DiVA (Digitala Vetenskapliga Arkivet), HAFAS (Das HaCon Fahrplan-Auskunfts-System, now owned by Siemens), and Open Street Map. Alternatively, data can be obtained by way of existing navigation network suites such as Vision Traffic Suite from PTV Group. The exact source of the data is not critical to the method of this disclosure, and is not intended to be limiting.

On the supply side, the transportation simulation program can allow designers to input a wide variety of transportation information, including roads, traffic and public transport supply for the desired location by integrating public transport timetables into the tool. One benefit of some described embodiments may include an increased level of accuracy when predicting a result associated with transportation simulations, in part because real-time data can be utilized for the simulation construction and inputs. On the demand side, the MTST may obtain data from a variety of sources including publicly and commercially available data for the desired location, and passenger ticketing information and passenger surveys, among other sources, including internal and outside sources. The MTST can also provide means that allow designers to import data from the most common systems via interfaces connected to publicly available data sources online. The import datasets may include, for example, road and public transport networks or timetables.

The quantitative analysis of the network and services can further include accounting for statistical data of geo-bound area usage, such as, for example, a number of residents and jobs in the traffic zones examined, and comparing them with the data of locally relevant destinations. Moreover, the MTST can be calibrated to present traffic conditions to better reflect realistic road network travel times.

In this regard, the output of the MTST may include a transportation network simulation such as one or more Origin-Destination (OD) Matrices, and OD trip pairings derived from the OD matrices, which may describe people movement in the geo-bound area(s).

There are several art-recognized models that can be employed to estimate an OD matrix, such as a gravity model and a gravity opportunity model, both of which may be appropriate for use in the described method. The creation of an OD matrix typically involves an iterative process in which a ratio of assigned OD trips in an initial matrix are evaluated, and the ratios between the types of trips are modified and reassigned within a modified trip matrix until a statistically acceptable trip table and assignment is generated.

The primary concept in this regard is to find a reasonable OD table that will reproduce known traffic counts. In large networks, different OD tables that may reproduce traffic counts with equal quality may be utilized. Most algorithms available today supplement the traffic counts with a “seed” OD table that is a best-guess approximation of the desired result. To this end, a seed OD table may be any of: one that has been observed in the past, one that has been observed recently but imprecisely, or one developed from principles of driver behavior.

In addition to creating OD matrices, MTST allows various OD trips within the OD matrix to be segregated. For example, the software allows the designer to segregate one class of trips, e.g., shared service OD trips, from other classes, e.g., private OD trips.

The MTST is also capable of producing a network assignment model. In this regard, the concepts of travel network assignment and Origin-Destination travel demand estimation are closely related to each other, due to the fact that a traffic assignment model provides users' route choice information and allocates traffic trips to different travel types and/or different road segments of a network, while most current OD matrix estimation techniques require users' route choice information to infer the OD matrix. Put another way, network assignment models are used to estimate the flow of users on a transportation network. These models may take a matrix of flows as an input, which can indicate the volume of traffic between origin and destination (OD) pairs. They also take input on the network topology, link characteristics, and link performance functions. The flows for each OD pair are loaded onto the network based on the travel time or impedance of the alternative paths that could carry this traffic.

Network assignment models broadly relate to finding connections from the origin to destination pairings and assigning the usage of each type of connection to the various OD pairs. There are number of art-recognized assignment methods including (i) transport-based assignments, (ii) frequency-based assignments, and (iii) schedule-based assignments. Transport-based assignments are the most straightforward as these focus on the available travel network and associated travel times for the network.

On the other hand, the schedule-based assignments are considered among the most complex methods insofar as these assume the highest level of knowledge on the part of passengers. As described in embodiments of the present disclosure, the passengers may be aware of published schedules for the transportation network being considered. Irrespective of the assignment method employed, the MTST can produce a network assignment model for the OD pairings in question.

In addition to the foregoing transportation tools, the emergence of microtransit systems have led to the advent of another class of simulations. This class of simulations seek to simulate the Mobility as a Service (MasS) microtransit system of a transportation network. Thus, a second type of travel simulation employed in the disclosed method may include a Shared Mobility Simulation tool (SMST).

SMSTs allow the assessment of a variety of MaaS concepts and are designed to be integrated with the existing multi-modal transport infrastructure. SMSTs can provide valuable assistance to shared service operators in designing feasible transportation services in consideration of existing city transport system performance and patterns, fleet/vehicle configurations and operating cost/revenue scenarios.

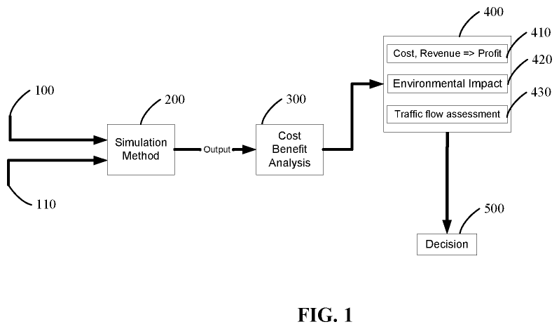

In turning to the method of this disclosure, FIG. 1 is a flow diagram illustrating an overview of a cost-benefit analysis method. As can be seen, the disclosed method includes both a simulation method step, e.g., a combined simulation/experimental design analysis, 200 and a cost-benefit analysis step 300.

The simulation method 200 involves the use of both an MTST and an SMST, which methods derive an output that is introduced into the cost-benefit analysis step 300. The input for simulation method 200 is derived from known, static inputs 100, (e.g., desired geographic location for the service, and an initial OD matrix), and variable travel parameters 110. While the simulation method step 200 can relate to the analysis of a single simulated system, it is preferable and contemplated that a plurality of simulated microtransit systems be run as a full-factorial analysis, and these disclosed methods are intended as being non-limiting.

The output of the simulation method step 200 includes a plurality of KPIs for the proposed system which can be employed in calculating both the costs associated with each simulated microtransit network and the benefits of each simulated microtransit network.

An output 400 of a cost-benefit analysis 300 for the simulated system includes decision-making parameters such as an expected operating cost, revenue and profit for simulated system 410, an environmental impact 420 of the simulated system, and a traffic flow assessment 430 for the simulated system. When the designer of the proposed microtransit system reviews the output 400, a decision 500 as to which microtransit system, if any, to move forward with, can be based on a comparison of the benefits and the costs.

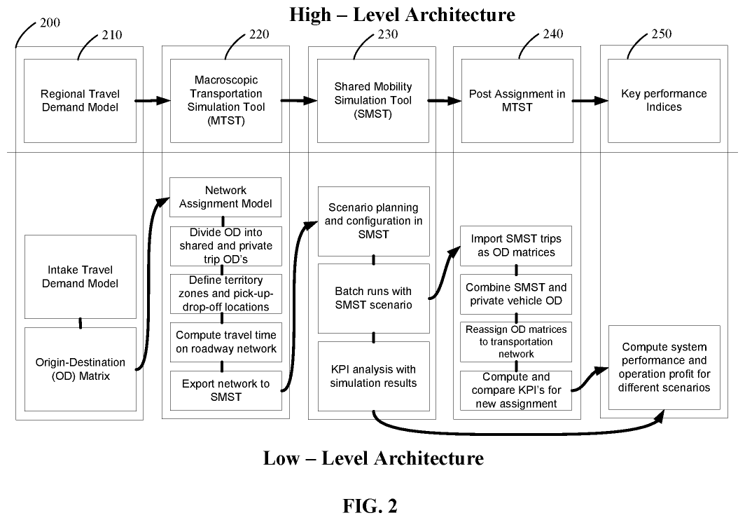

FIG. 2 illustrates one embodiment of the overall simulation/experimental design step analysis of the disclosed method. As shown in FIG. 2 the high-level architecture of the simulation step 200 can start with a transportation network simulation for a desired geographic area. For example, a regional travel demand model 210 can provide transportation assignment data for an initial OD matrix. This initial model 210 can include OD pairings for both private and shared rides. The initial model 210 is introduced into a Macroscopic Transportation Simulation Tool (MTST) 220.

The output of the MTST 220 includes a transportation network simulation focusing on the proposed microtransit system, such as, for example, a network assignment for the microtransit specific OD matrix/trip pairings that is introduced into a Shared Mobility Simulation Tool (SMST) 230.

Based on this information, the SMST 230 can calculate (i) the fleet sizes needed to complement existing transport systems (ii) relevant Key Performance Indices (KPIs) with respect to the business model for Mobility as a Service (MaaS) Fleets within a desired location, (iii) operational and service parameters for the system, (iv) model MaaS fleet operations within a multimodal traffic system, and (vi) a MaaS fleet's potential usage.

In this regard, the desired output from the SMST 230 for purposes of this disclosure can include microtransit system specific simulation data including, for example, (i) an OD matrix of microtransit trips for the microtransit system being considered and (ii) a range of performance factors for the microtransit system.

One portion of the output from the SMST 230 includes revised OD matrices for a simulated microtransit system that is introduced back to a post assignment in MTST 240.

The MTST 240 can then provide a revised simulation that includes, for example, a combination of the generated microtransit system-specific OD trip requests from the microtransit system-specific OD matrix with the private trip OD trip requests that were previously separated out from the initial OD matrix. The combination of shared OD trips and private OD trips in the MTST forms the basis for the creation of a revised OD matrix for the desired geographic region in the same manner as the original OD matrix was calculated.

The SMTS 230 also generates Key Performance Indices (KPI) for the proposed microtransit system. The method of this disclosure also provides for the analysis of one or more Key Performance Indices (KPI) 250 for the simulated microtransit system, which data can be compared to other simulated systems.

A first aspect of one embodiment of the method of this disclosure includes the generation of an initial Origin-Destination (OD) matrix for the desired geographic area using a transport design Regional Travel Demand model, 210, of FIG. 2. Suitable transport design models are well recognized in the art and need not be described in further detail here.

The method can then employ the MTST simulation tool (220, FIG. 2) to target demand for the desired microtransit system. In this embodiment, the initial OD matrix can be introduced into the MTST. These features of this example MTST can be illustrated by the lower level architecture for step 220 of FIG. 2.

Specific examples of suitable commercially available MTST tools which can be employed in providing the functionality needed for the disclosed method include PTV Group's Visum; Anylogic 7; MATSim; TransCAD; TRANSIMS; Simulation of Urban MObility (SUMO); Aimsun Next; TransModeler; and Quadstone Paramics.

In short, MTSTs may employ publicly or commercially available travel data including demographics, roads and transit systems, and use commercially available real time traffic data for vehicle demand, by developing a preliminary model of travel time, speed, and origin and destination information for various microtransit modalities. Specifically, as one example of the steps performed by the MTST, the tool first effectively divides the desired location into a number of travel origination/destination zones.

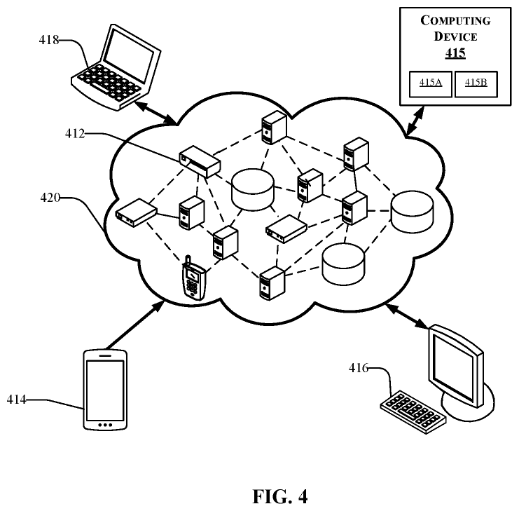

Second, the inputted data relating to trips is applied to the zones and a matrix, an origin and destination (OD) matrix. The MTST may create one or more OD matrices to illustrate a respective number of trips from one travel zone to another. An OD matrix can be illustrated as a matrix in chart form. Alternatively, the OD matrix can be illustrated graphically as a numeric matrix or series of OD trips overlaid on a map of a particular geo-bound area. From the OD matrix, the MTST may create, identify and/or define one or more series of OD trip pairings, which may represent trips from one zone to another. This data can be illustrated graphically or in matrix form on a user interface, such as a desktop computer 416 or a laptop computer 418, as described with respect to FIG. 4.

Moreover, this segregation involves consideration of a number of factors associated with the OD matrix. These factors include selecting which of the origination/destination zones and corresponding OD trip pairings from the OD matrix will be considered as relating to shared trips or private trips. Moreover, suitable pickup and drop off locations within the territory zones are also defined to help segregate the OD pairings for shared service from private transport. Finally, the expected travel times for the OD trips can be computed and employed to aid in determining the segregation of shared and private trips. The extraction of shared service demand from the OD matrix can serve as the starting basis for trip requests for the microtransit service.

Segregation of the OD data by the MTST can further help determine the expected number of service vehicles that will be initially required for the proposed system. That is, an initial value for the expected number of service vehicles can be derived from the initial expected number of microtransit trip requests obtained from segregation of the shared OD trips.

The expected demand, i.e., a preselected value, e.g., from 3%-15% of the total number of expected microtransit trips can also be calculated. The number of vehicles, i.e., fleet size, is then determined based on expected demand. As a suitable technique for establishing a base fleet size, a set of calibration runs identifies the minimum necessary fleet size to ensure that a desired percentage of expected demand will be served. Alternative fleet size, e.g., a number greater or less than the base fleet, can be used to evaluate the impact of varying fleet size to the microtransit trip service.

The output of the MTST is a transportation network simulation for the proposed microtransit system that can then introduced into a second simulation tool. As discussed above, the second simulation tool employed in the method of the present disclosure is a Shared Mobility Simulation tool (SMST) 230.

SMSTs suitable for use in the present disclosure are typically capable of taking all participating transport operators' information from their static and real-time data feeds and processing them via its mixed modal routing engine to create trip routings and options using any combination of private, public and commercial transport. Examples of SMSTs can include the following companies and/or associated SMSTs including PTV-MaaS Modeler: A-to-Be-MoveBeyond® and LinkBeyond®; SkedGo®-TripGo®; MaaS Global®; and Conduent®. Other SMSTs may be suitable as well, and such tools are possible and contemplated for use in disclosed methods, which should not be considered limiting.

One example of a particularly suitable SMST is the MaaS Modeler software available from PTV Group. Specifically, MaaS Modeler is a cloud software solution which can calculate, for example, both an OD matrix and a variety of performance factors for a public transport system.

In employing the MaaS Modeler as the SMST, the input can include both static and/or real time data feeds. The static feed may include a network assignment model of OD trips, such as those which can be obtained from the MTST for the desired travel network as well as a variety of other variables, i.e., performance factors, for the desired microtransit system.

Example performance factors can include (i) maximum wait time, i.e. how long a passenger is willing to wait to be picked up, (ii) maximum detour factor, i.e., how much extra time a passenger is willing to spend on a microtransit trip compared to a private vehicle trip, as a ratio between the two times., (iii) demand, i.e., what percent of trips are replaced by a microtransit trip. Demand can initially assume a fixed demand profile, but this disclosure also contemplates the ability to discreetly model which people will choose to take microtransit; (iv) pick-up and drop-Off (PUDO) location density (this disclosure contemplates both the use of pre-determined or variable pick-up and drop-off points in the system, and should not be considered as limiting); and (v) fleet size/coverage, i.e. the number of vehicles in the microtransit fleet and the fleet hours of operation.

The importance of these performance factors lies in their ability to be used to provide a range of Key Performance Indices (KPI) which are analyzed to determine the effectiveness of service operation, cost and profitability of deploying the service under consideration. Specific examples of KPIs that can be derived in the method of this disclosure may include (1) a factor of detours experienced, which may describe an observed average detour time (including waiting time) a passenger experiences as divided by the service period; (2) Vehicle Miles Travelled (VMT), which can describe daily miles driven per vehicle; (3) Vehicle Utilization, also known as, Vehicle Hours Travelled (VHT), which may describe a number of hours per day a particular vehicle is being used, including picking up and dropping off passengers, travelling with passengers, and travelling without passengers; (4) Vehicle Occupancy which may describe a measure of the degree of vehicle utilization over distance, obtained by the ratio of passenger miles to VMT (i.e., more deadheading decreases occupancy while more sharing increases occupancy); (5) Daily Trips per Vehicle—how many travelers each vehicle serves per day); (6) Passenger miles traveled (PMT) per day; (7) Passenger hours traveled (PHT) per day; (8) Congestion mitigation as represented, e.g., by the percent reduction in VMT/VHT; (9) Environmental Impacts, e.g., the effects on CO₂ emissions for the microtransit system; and (10) Vehicle Profitability, i.e., how much money each of the shared vehicles makes (or loses) per day.

The method of this disclosure further includes the step of determining and analyzing a plurality of Key Performance Indices (KPIs) for revised transportation network simulations derived from the SMST using a full-factorial analysis of performance factors and using the thus-determined KPIs to calculate the expected costs and benefits of the revised transportation network simulations. The ability to calculate KPIs is a core feature of the SMST tool and as such does not need to be described in detail here.

The calculation of the KPI for a single microtransit example from the SMST can be limiting in its usefulness. For example, with a single set of data, the developer may be unable to get a full picture of the limitations and possibilities of the proposed microtransit system.

To this end, the present disclosure includes both a transportation simulation and an experimental design scenario. In statistics, a full factorial experiment is an experiment whose design consists of two or more factors, each with discrete possible values or “levels,” and whose experimental units take on all possible combinations of these levels across all such factors. A full-factorial design may also be called a fully crossed design. Such an experiment allows the investigator to study the effect of each factor on the response variable, as well as the effects of interactions between factors on the response variable.

Here, a series of full-factorial dynamic experiments are run to identify the impacts of certain performance factors, i.e., independent variables, on microtransit service from the perspectives of travelers, system designers/operators, and city transportation planners.

As a suitable technique in comparing the impact of each performance factor on the system, the SMST is repeated a predetermined number of times in the form of a series of batch runs depending on the designated performance factors. In one embodiment, the full-factorial analysis includes a batch run for each of a base value and an alternative value for each of the performance factors selected.

In the context of this disclosure, the performance factors may include one or more of the following factors with suitable values based on existing commercial microtransit data.

One factor is maximum wait time, i.e. how long a passenger is willing to wait to be picked up from the microtransit service. Suitable values for this factor include, for example, 5 to 15 minutes.

Another factor is maximum detour factor, i.e., how much extra time a passenger is willing to spend on a microtransit trip compared to a private vehicle trip. Suitable values, as calculated as ratio between the microtransit time and the private vehicle time are, for example, a factor rate from 2 to 3.

A third factor is demand, i.e., what percent of trips are replaced by microtransit trips. Suitable values range, for example, from about 3-15%. While the suitable values can be based on a fixed demand profile, it is also within the scope of this disclosure to dynamically calculate the value based on the determination of which passengers will choose to take the microtransit under consideration.

A fourth factor is pick-up and drop-off (PUDO) location density. In calculating this factor, the pickup and drop-off locations can either be pre-determined or variable points in the system. For example, the pick-up and drop-off (PUDO) location density can vary from 50 m spacing (corresponding to about a 45 second walk for the passenger) to about a 400 m spacing (corresponding to a 5-minute walk).

A fifth factor is fleet size—the number of vehicles employed in the microtransit fleet. This value relates to the number of vehicles needed to serve a predetermined percentage of the expected microtransit demand. The fleet size can have, for example, a base value for number of vehicles which would be targeted to serve about 99%, of expected demand, which can alternatively be characterized as about 1% unserved demand. Fleet size can also have an alternative value for number of vehicles which is about 15% less than the base value.

A final factor relates to service hours, where the SMST factor can involve identifying profitable hours in which to operate the services.

The values for the factors discussed above are suitable and exemplary but in no way are meant to limit the disclosed process. Particular values for a desired geographic location can be readily determined by those skilled in the art.

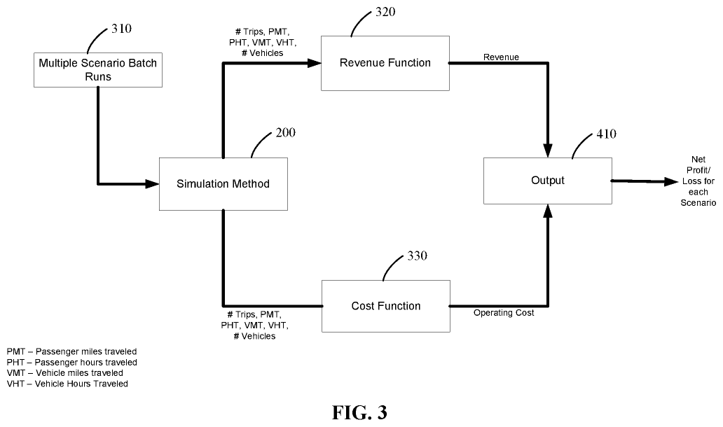

The KPI results of the Full-Factorial analysis can then be subjected to a Cost-Benefit Analysis as illustrated in FIG. 3. The Full-Factorial simulation/experimental design step 200 has an input 310 which includes a plurality of design parameters which are capable of providing the full-factorial batch runs in the simulation method 200 step. The output from the simulation method 200 step can include one or more KPI for each of the batch runs.

To this end, a cost-benefit analysis output 410 for the various simulated systems is performed by considering and comparing both the costs function 330 and benefits function 320 based on the resulting KPI. The output of steps 320 and 330 results in the operating costs and revenue/benefits of systems tested.

The calculation of operating cost can be based on a number of recognized parameters such as cost per mile amounts obtained from the IRS, per-hour labor cost, per-day fixed cost (i.e. system management), and per-vehicle daily cost for operation. Going forward, designers can obtain direct estimates to build detailed cost models specific to given use cases. Different service models and areas will have different cost and revenue predictions.

The methods of this disclosure can be practiced by a computer system, such as a cloud-based computer system broadly illustrated by FIG. 4. Specifically, the software and data associated with each of the method steps can be stored and accessed on servers located via the internet rather than on site. This should not be considered limiting however, and it is within the scope of this disclosure and contemplated that the system can also be located in servers on site with the end users.

In FIG. 4, a computing device 415 including components such as processor 415A and memory 415B, is in communication with a cloud system network 420 that includes a plurality of storage devices 412. The cloud can be accessed by a variety of computer devices including handheld computers 414, a desk top computer(s) 416 and a laptop computer(s) 418.

To that end, the computer system suitable for practicing the method of this disclosure may include one or more processor(s), and a memory communicatively coupled to the one or more processor(s). The computer may operatively connect to and communicate information with one or more internal and/or external memory devices such as, for example, one or more databases via a storage interface. For example, in one embodiment, the computer may connect to and communicate information with an internal and/or external database, such as a profile database (referenced as the user data).

The computer may include one or more network adaptor(s) (not shown in FIG. 4) enabled to communicatively connect the computer with the one or more network(s). In some example embodiments, the network(s) may be or include a telecommunications network infrastructure. In such embodiments, the computer can further include one or more communications adaptor(s).

The computer may further include and/or connect with one or more input devices and/or one or more output devices (not shown in FIG. 4)) through an I/O adapter.

The one or more processor(s) are collectively a hardware device for executing program instructions (software), stored in a computer-readable memory. The one or more processor(s) may embody a custom made or commercially-available processor, a central processing unit (CPU), a plurality of CPUs, an auxiliary processor among several other processors associated with the computer, a semiconductor based microprocessor (in the form of a microchip or chipset), or generally any device for executing program instructions.

The one or more processor(s) may be disposed in communication with one or more memory devices (e.g., the memory and/or one or more external databases, etc.) via a storage interface. The storage interface can also connect to one or more memory devices including, without limitation, one or more other memory drives, including, for example, a removable disc drive, cloud storage, etc., employing connection protocols such as serial advanced technology attachment (SATA), integrated drive electronics (IDE), IEEE-1394, universal serial bus (USB), fiber channel, small computer systems interface (SCSI), etc.

The memory can include random access memory (RAM) such as, for example, dynamic random access memory (DRAM), synchronous random access memory (SRAM), synchronous dynamic random access memory (SDRAM), etc., and read only memory (ROM), which may include any one or more nonvolatile memory elements (e.g., erasable programmable read only memory (EPROM), flash memory, electronically erasable programmable read only memory (EEPROM), programmable read only memory (PROM), tape, compact disc read only memory (CD-ROM), etc.). Moreover, the memory can incorporate electronic, magnetic, optical, and/or other types of non-transitory computer-readable storage media. In some example embodiments, the memory may also include a distributed architecture, where various components are physically situated remotely from one another, but can be accessed by the one or more processor(s).

The instructions in the memory can include one or more separate programs, each of which can include an ordered listing of computer-executable instructions for implementing logical functions. The instructions in the memory can include an operating system.

The program instructions stored in the memory can further include application data, and instructions for controlling and/or interacting with the computer through a user interface. The application data may include, for example, one or more databases.

The I/O adapter can connect a plurality of input devices to the computer. The input devices can include, for example, a keyboard, a mouse, a microphone, a sensor, etc. The I/O adapter can further include a display adapter coupled to one or more displays. The I/O adapter can be configured to operatively connect one or more input/output (I/O) devices to the computer. For example, the I/O adapter can connect a keyboard and mouse, a touchscreen, a speaker, a haptic output device, or other output device. The output devices can include but are not limited to a printer, a scanner, and/or the like. Finally, the I/O devices connectable to the I/O adapter can further include devices that communicate both inputs and outputs, for instance but not limited to, a network interface card (NIC) or modulator/demodulator (for accessing other files, devices, systems, or a network), a radio frequency (RF) or other transceiver, a telephonic interface, a bridge, a router, and the like.

As can be seen, the method and system of the present disclosure has a broad scope of applicability in the transportation field. For example, it is capable of being applied across a wide variety of geographic areas of varying sizes and population densities, not to mention a wide cross-section of transportation networks, microtransit systems and their service parameters. In fact, this method can be expanded to other forms of mobility services, such as, micro mobility solutions.

The disclosed methods can provide a number of advantages over existing simulations. For example, the method can provide a cost-benefit analysis of a number of possible microtransit scenarios at the same time, thus, providing a fast decision-making process and a more efficient business operation.

Moreover, the method is in the form of a fully digital tool, independent of any specific commercial simulation tool or data type, which aids in determining both market access and market profitability. In fact, the method can identify cases and constraints under which shared mobility services may thrive from the operator's perspective including the optimal service operation for various geographic locations based on the demand profiles and the travel needs for those locations.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method for performing a cost-benefit analysis for a microtransit system in a desired geographic area comprising:
creating a transportation network simulation of a proposed microtransit system in a geographic area utilizing a Macroscopic Transportation Simulation (MTST) tool;
performing a full-factorial analysis of the proposed microtransit system comprising a series of batch simulation runs of selected independently variables for the proposed microtransit system utilizing a Shared Mobility Simulation tool (SMST) comprising independent variables;
creating a revised transportation network simulation for the desired geographic area for each batch run of the proposed microtransit system utilizing MTST;
calculating a plurality of Key Performance Indices (KPIs) for the proposed microtransit system for each of the revised transportation network simulations; and
performing a cost-benefit analysis based on the KPIs to evaluate the proposed microtransit system.

2. The method of claim 1, wherein the microtransit system is one of a city-scale deployment of microtransit services, a first-mile/last-mile shuttle, a non-emergency medical transportation (NEMT), the microtransit system replacing low frequency/low utilization buses, park-and-ride, event-transportation, and service expansion for transit authorities or an alternative mobility service.

3. The method of claim 1, where the independent variables for the SMST include a maximum number of service vehicles utilized in the microtransit system full-factorial analysis.

4. The method of claim 3, wherein the maximum number of service vehicles included in the full-factorial analysis comprises a base value of about 1% unserved demand and an alternative value which is 15% less than the base value.

5. The method of claim 1, wherein the independent variables for SMST include a maximum wait time for passengers in the full-factorial analysis.

6. The method of claim 5, wherein the maximum wait time included in the full-factorial analysis comprises a base value of 5 minutes and an alternate value of 15 minutes.

7. The method of claim 1, wherein the independent variables for SMST include a maximum detour factor for passengers in the full-factorial analysis.

8. The method of claim 7, wherein the maximum detour factor included in the full-factorial analysis comprises a base value of 2 and an alternate value of 3.

9. The method of claim 1, wherein the independent variables for SMST include a pick-up and drop-off location density for passengers in the full-factorial analysis.

10. The method of claim 9, wherein the pick-up and drop-off location density included in the full-factorial analysis comprises a base value of 50 m spacing and an alternate value of 400 m spacing.

11. The method of claim 9, wherein the pick-up and drop-off location density included in the full-factorial analysis comprises a base value of about a 45 second walk for a user and an alternate value of about a 5-minute walk for a user.

12. The method of claim 1, wherein the independent variables for SMST include microtransit system demand in the full-factorial analysis.

13. The method of claim 12, wherein microsystem demand included in the full-factorial analysis comprises a base value of about 3% of private vehicle trips and an alternate value of 15% of private vehicle trips.

14. The method of claim 1, wherein the full-factorial analysis includes a batch run for each of a base value and an alternative value for each of the selected independent variables.

15. The method of claim 1, wherein the KPIs include one or more of:
vehicle miles traveled (VMT) per day;
vehicle hours traveled (VHT) per day;
passenger miles traveled (PMT) per day;
passenger hours traveled (PHT) per day;
passenger experienced detour factor;
daily trips per vehicle; vehicle occupancy; and
profitability per vehicle.

16. The method of claim 1, wherein the cost-benefit analysis includes comparing one or more of operating cost, traffic flow assessment and environment impact for batch runs of SMST.

17. A system, comprising:
a processor; and
a memory for storing executable instructions, the processor configured to execute the instructions to:
create a transportation network simulation of a proposed microtransit system in a desired geographic area utilizing a Macroscopic Transportation Simulation (MTST);
perform a full-factorial analysis of the proposed microtransit system comprising a series of batch simulation runs of selected independently variables for the proposed microtransit system utilizing a Shared Mobility Simulation tool (SMST);
create a revised transportation network simulation for the desired geographic area for each batch run of the proposed microtransit system utilizing the MTST;
calculate a plurality of Key Performance Indices (KPIs) for the proposed microtransit system for each of the revised transportation network simulations; and
perform a cost-benefit analysis based on the KPIs to evaluate the proposed microtransit system.

18. The system of claim 17, wherein a microtransit system is one of a city-scale deployment of microtransit services, a first-mile/last-mile shuttle, a non-emergency medical transportation (NEMT), the microtransit system replacing low frequency/low utilization buses, park-and-ride, event-transportation, and service expansion for transit authorities or alternative mobility service.

19. The system of claim 17, where the independent variables for the SMST in the full-factorial analysis include one or more of a maximum number of service vehicles utilized in a microtransit system, maximum passenger wait time, maximum passenger detour factor, passenger pick-up and drop-off density and demand.

20. A non-transitory computer-readable storage medium, the computer-readable storage medium having instructions stored thereupon which, when executed by a processor, cause the processor to:
create a transportation network simulation of a proposed microtransit system in a desired geographic area utilizing a Macroscopic Transportation Simulation (MTST);
perform a full-factorial analysis of the proposed microtransit system comprising a series of batch simulation runs of selected independently variables for the proposed microtransit system utilizing a Shared Mobility Simulation tool (SMST);
create a revised transportation network simulation for the desired geographic area for each batch run of the proposed microtransit system utilizing the MTST;
calculate a plurality of Key Performance Indices (KPIs) for the proposed microtransit system for each of the revised transportation network simulations; and
perform a cost-benefit analysis based on the KPIs to evaluate the proposed microtransit system.
